(19) United States
(12) Patent Application Publication
(10) Pub. No.: US 2016/0351377 A1
(43) Pub. Date: Dec. 1, 2016

(54) ION BEAM ETCHING APPARATUS AND ION BEAM GENERATOR

(71) Applicant: CANON ANELVA CORPORATION, Kawasaki-shi (JP)

(72) Inventors: Naoyuki OKAMOTO, Kawasaki-shi (JP); Yoshimitsu KODAIRA, Kawasaki-shi (JP); Yasushi YASUMATSU, Kawasaki-shi (JP)

(21) Appl. No.: 15/084,593

(22) Filed: Mar. 30, 2016

(30) Foreign Application Priority Data
Jun. 1, 2015 (JP) 2015-111701

(51) Int. Cl. H01J 37/32

(52) U.S. Cl. CPC H01J 37/32532; H01J 37/32321; H01J 37/32715; H01J 2237/334

(57) ABSTRACT

An ion beam etching apparatus includes: a processing chamber connected to the plasma generation chamber including an internal space; a plasma generating unit configured to generate plasma in the internal space; an extracting unit configured to extract ions from the plasma, from the internal space to the processing chamber, the extracting unit including first, second and a third electrodes, each of which has a plurality of ion passage holes; a first ring member provided closer to the plasma generation chamber; a second ring member provided closer to the processing chamber; a fixing member having one end and another end, the fixing member penetrating the first, second and third electrodes, and having the one end connected to the first ring member and the other end connected to the second ring member; and a heating unit configured to heat the third electrode from outside of the plasma generation chamber.

### CROSS-REFERENCES TO RELATED APPLICATIONS

This application is based upon and claims the benefit of priority of the prior Japanese Patent Application No. 2015-111701, filed Jun. 1, 2015. The contents of the aforementioned application are incorporated herein by reference in their entireties.

### BACKGROUND OF THE INVENTION

Field of the Invention

The present invention relates to an ion beam etching apparatus and an ion beam generator.

Description of the Related Art

In a technology to manufacture a semiconductor device, ion beam etching (hereinafter also referred to as IBE) is used to form various patterns. Such an IBE apparatus generates plasma by introducing gas into an ion source and using appropriate means, extracts ions from the plasma and performs etching by irradiating an object to be processed with the ions.

The IBE apparatus generally uses a plurality of grids to extract ions from plasma. The plurality of grids are generally fixed at their ends to prevent positional misalignment among holes thereof (see Japanese Patent Application Laid Open No. 2011-129270).

### SUMMARY OF THE INVENTION

During the IBE process, chamber walls, fixation rings for fixing a plurality of grids, or the like are thermally expanded by heat input from the plasma. As for the grids, the temperature of a grid on the plasma side is increased by heat from the plasma, while an increase in temperature of a grid on the substrate side is smaller than that of the grid on the plasma side. Thus, the amount of thermal expansion in the grid on the plasma side is large, and then the thermal expansion causes a force pressing the fixing member outward. On the other hand, the amount of thermal expansion in the grid on the substrate side is smaller than that in the grid on the plasma side.

With the recent increase in size of substrates to be processed, grids also have been increased in size. The increase in size of grids increases the amount of thermal expansion, and deflections occur on the grids in the structure with the grids fixed at their ends. The deflections on the grids may cause positional misalignments of grid holes between the substrate side and the plasma side. Moreover, the deflections on the grids may cause gap differences among the grids, so that the gap among the grids becomes wider and narrower. Such positional misalignments of the grid holes or gap differences among the grids may become causes of changing an irradiation direction of the ion beam or temporarily reducing an irradiation amount.

The present invention has been made in consideration of the above problems. It is an object of the present invention to provide an ion beam etching apparatus and an ion beam generator, capable of reducing positional misalignments of grid holes and gap differences among grids even when large grids are used.

To achieve this object, a first aspect of the present invention is an ion beam etching apparatus including: a plasma generation chamber including an internal space; a processing chamber connected to the plasma generation chamber; a plasma generating unit configured to generate plasma in the internal space; an extracting unit configured to extract ions from the plasma, from the internal space to the processing chamber, the extracting unit including a first electrode, a second electrode and a third electrode, each of which has a plurality of ion passage holes for passing the ions, the first electrode being provided closest to the plasma generation chamber, the second electrode being provided closer to the processing chamber than the first electrode, the third electrode being provided closest to the processing chamber; a first ring member provided closer to the plasma generation chamber than the first electrode, the first ring member overlapping with a peripheral portion of the first electrode outside a region where the plurality of ion passage holes in the first electrode are formed, such that the plurality of ion passage holes formed in the first electrode are exposed through the first ring member; a second ring member provided closer to the processing chamber than the third electrode, the second ring member overlapping with a peripheral portion of the third electrode outside a region where the plurality of ion passage holes in the third electrode are formed, such that the plurality of ion passage holes formed in the third electrode are exposed through the second ring member; a fixing member having one end and another end, the fixing member penetrating the first electrode, the second electrode and the third electrode, and having the one end connected to the first ring member and the other end connected to the second ring member; a heating unit configured to heat the third electrode from outside of the plasma generation chamber; and a substrate holder provided in the processing chamber and capable of holding a substrate, the substrate holder being provided to receive the ions extracted by the extracting unit.

A second aspect of the present invention is an ion beam generator including: a plasma generation chamber including an internal space; a plasma generating unit configured to generate plasma in the internal space; an extracting unit configured to extract ions from the plasma, from the internal space to an outside of the plasma generation chamber, the extracting unit including a first electrode, a second electrode and a third electrode, each of which has a plurality of ion passage holes for passing the ions and which are arranged along a predetermined direction such that surfaces where the ion passage holes are formed face each other, the first electrode being provided closest to the plasma generation chamber, the third electrode being provided farthest from the plasma generation chamber along the predetermined direction and the second electrode being provided between the first electrode and the third electrode; a first ring member provided closer to the plasma generation chamber than the first electrode, the first ring member overlapping with a peripheral portion of the first electrode outside a region where the plurality of ion passage holes in the first electrode are formed, such that the plurality of ion passage holes formed in the first electrode are exposed through the first ring member; a second ring member provided farther from the plasma generation chamber along the predetermined direction than the third electrode, the second ring member overlapping with a peripheral portion of the third electrode outside the region where the plurality of ion passage holes in the third electrode are formed, such that the plurality of ion passage holes formed in the third electrode are exposed through the second ring member; a fixing member having one end and another end, the fixing member penetrating the first electrode, the second electrode and the third electrode, and having the one end connected to the first ring member and the other end to the second ring member; and a heating unit configured to heat the third electrode from outside of the plasma generation chamber.

According to the present invention, the positional misalignments of grid holes between the substrate side and the plasma side can be reduced and the gap differences among the grids can be reduced even when large grids are used.

### BRIEF DESCRIPTION OF THE DRAWINGS

FIG. 1 is a schematic diagram of an ion beam etching apparatus according to a first embodiment of the present invention.

FIG. 2 is a schematic diagram for explaining a grid and a heating unit configured to heat a third electrode in the grid according to the first embodiment of the present invention.

FIG. 3 is a diagram showing how the grid is fixed to a ring member according to the first embodiment of the present invention.

FIG. 4 is a diagram for explaining connection between the grid and the ring member according to the first embodiment of the present invention.

FIG. 5 is a diagram showing a configuration to control the temperature of the third electrode in the grid according to the first embodiment of the present invention.

FIG. 6 is a schematic diagram for explaining a grid and a heating unit configured to heat a third electrode in the grid according to a second embodiment of the present invention.

FIG. 7 is a top view of a ring member according to a third embodiment of the present invention.

### DESCRIPTION OF THE EMBODIMENTS

With reference to the drawings, embodiments of the present invention are described below. However, the present invention is not limited to the embodiments described below. Note that, in the drawings described below, components having the same functions are denoted by the same reference numerals, and repetitive description thereof may be omitted.

### First Embodiment

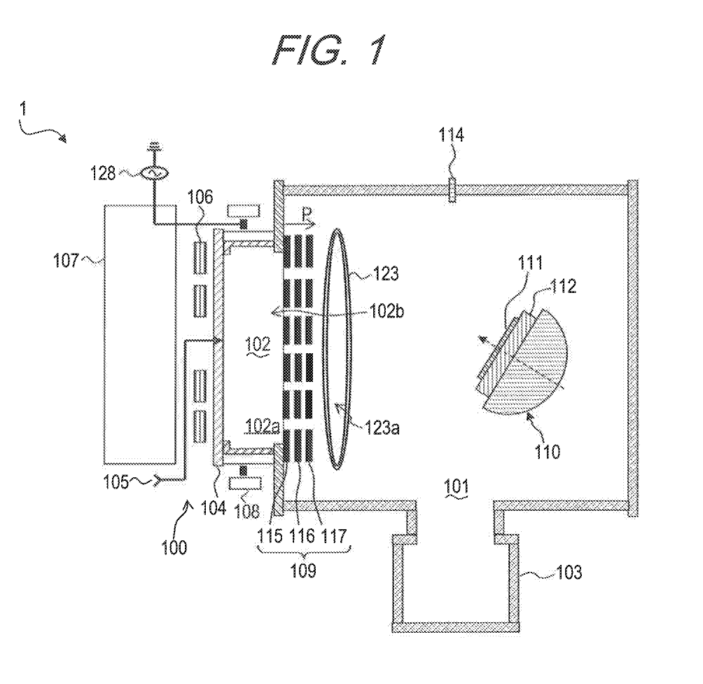

FIG. 1 shows a schematic diagram of an ion beam etching apparatus according to this embodiment. An ion beam etching apparatus 1 includes a processing chamber 101 and an ion beam generator 100 provided so as to radiate ion beams into the processing chamber 101. The ion beam generator 100 and the processing chamber 101 are connected to each other, and thus the ion beams generated by the ion beam generator 100 are introduced into the processing chamber 101.

Inside the processing chamber 101, a substrate holder 110 capable of holding a substrate 111 is provided so as to receive the ion beams radiated from the ion beam generator 100. The substrate holder 110 provided inside the processing chamber includes an ESC (Electrostatic Chuck) electrode 112 on the ion beam-incident side. The substrate 111 is placed on the ESC electrode 112 and electrostatic attraction and held by the ESC electrode 112. The substrate holder 110 can be arbitrarily tilted with respect to the ion beams. Also, the substrate holder 110 has a structure that allows the substrate 111 to turn (rotate) in its in-plane direction.

Moreover, the processing chamber 101 is provided with an evacuation pump 103 capable of evacuating the processing chamber 101 and a plasma generation chamber 102 to be described later. Inside the processing chamber 101, a neutralizer (not shown) is provided, which can electrically neutralize the ion beams introduced from the ion beam generator 100. Thus, the substrate 111 can be irradiated with the electrically neutralized ion beams, thereby preventing the substrate 111 from being charged up. The processing chamber 101 is also provided with a gas introduction unit 114 capable of introducing process gas into the processing chamber 101.

The ion beam generator 100 includes the plasma generation chamber 102. The plasma generation chamber 102 as a discharge chamber includes a discharge container 104 as a member having an internal space 102a that is a hollow part and an opening 102b. The internal space 102a serves as a discharge space in which plasma discharge is generated. In this embodiment, as shown in FIG. 1, the processing chamber 101 and the plasma generation chamber 102 are connected to each other by attaching the discharge container 104 made of quartz, for example, to the processing chamber 101 made of stainless steel or the like, for example. That is, the discharge container 104 is attached to the processing chamber 101 such that an opening formed in the processing chamber 101 overlaps with the opening 102b in the discharge container 104 (the opening 102b in the plasma generation chamber 102).

The internal space 102a is communicated with the processing chamber 101 outside thereof through the opening 102b, and ions generated in the internal space 102a are extracted from the opening 102b to the processing chamber. The plasma generation chamber 102 is also provided with a gas introduction unit 105, which introduces etching gas into the internal space 102a of the plasma generation chamber 102. Moreover, a RF antenna 108 for generating a radio frequency (RF) field is disposed around the plasma generation chamber 102 so as to generate plasma discharge in the internal space 102a. A discharge power source 128 for supplying high-frequency power to the RF antenna 108 is connected to the RF antenna 108 through a matching box 107. Furthermore, an electromagnetic coil 106 is provided around the plasma generation chamber 102. In such a configuration, plasma of the etching gas can be generated in the plasma generation chamber 102 by introducing the etching gas from the gas introduction unit 105 and applying the high-frequency power to the RF antenna 108. The RF antenna 108 and the discharge power source 128 function as a plasma generating unit configured to generate plasma in the internal space 102a.

In this embodiment, as shown in FIG. 1, the processing chamber 101 and the plasma generation chamber 102 are connected to each other. The ion beam generator 100 further includes a grid unit 109 as an extracting unit configured to extract ions from the plasma generated in the internal space 102a, the grid unit 109 being provided at the boundary between the processing chamber 101 and the plasma generation chamber 102 connected to each other. In this embodiment, the substrate 111 is processed by applying a DC voltage to the grid unit 109, extracting the ions in the plasma generation chamber 102 as a beam and irradiating the substrate 111 with the extracted ion beam. Note that, in FIG. 1, the grid unit 109 is attached to the apparatus by means of an unillustrated fastening member, and respective electrodes in the grid unit 109 are connected by an unillustrated connection part.

The grid unit 109 is provided in the opening 102b formed on the ion release side of the plasma generation chamber 102. The grid unit 109 includes a first electrode 115, a second electrode 116 and a third electrode 117 as at least three electrodes (grids). Each of the electrodes 115, 116 and 117 is a plate-like electrode having a large number of ion passage holes (grid holes) for passing the ions generated in the internal space 102a. The ion passage holes are formed so as to penetrate from one principal surface to another principal surface in each of the electrodes 115, 116 and 117. As for the material of the first electrode 115, the second electrode 116 and the third electrode 117, molybdenum, titanium, carbon, iron-nickel alloy, stainless steel, tungsten or the like can be used.

The first electrode 115, the second electrode 116 and the third electrode 117 are arranged at a distance from and in parallel with each other from the internal space 102a toward the outside of the opening 102b (along the travelling direction of the ion beam extracted by the grid unit 109) in the opening 102b. The first electrode 115, the second electrode 116 and the third electrode 117 are arranged in this order from the internal space 102a toward the outside of the opening 102b. The grid unit 109 including the first electrode 115, the second electrode 116 and the third electrode 117 thus arranged allows the ions from the internal space 102a to pass through the ion passage holes and to be released to the outside of the plasma generation chamber 102. Among these at least three electrodes 115, 116 and 117, the first electrode 115 that is the electrode closest to the internal space 102a functions as a member that defines a discharge space in the opening 102b, and the surfaces of the respective electrodes 115, 116 and 117 having the ion passage holes formed therein face each other.

In this embodiment, the grid unit 109 includes the first electrode 115, the second electrode 116 and the third electrode 117 in the order from the plasma generation chamber 102 side to the outside at the connection between the plasma generation chamber 102 and the processing chamber 101, i.e., the boundary therebetween. The first electrode 115 is a plasma-side grid which is the closest to the plasma generated in the plasma generation chamber 102, among the grids in the grid unit 109. The third electrode 117 is a substrate-side grid which is the closest to the substrate 111, among the grids in the grid unit 109. The first electrode 115, the second electrode 116 and the third electrode 117 are arranged in an arrangement direction P such that the ion passage holes in the first electrode 115, the ion passage holes in the second electrode 116 and the ion passage holes in the third electrode 117 face each other, respectively.

The first electrode 115 arranged along the arrangement direction P is provided closest to the internal space 102a (the closest to the plasma generation chamber) in the opening 102b. The first electrode 115 also functions as a member that defines the internal space 102a in the opening 102b. The second electrode 116 is provided farther from the internal space 102a than the first electrode 115 (closer to the processing chamber 101 than the first electrode 115), along the arrangement direction P from the first electrode 115 to the third electrode 117. The third electrode 117 is provided farther from the internal space 102a along the arrangement direction P from the first electrode 115 than the second electrode 116. The third electrode 117 is provided as the farthest from the plasma generation chamber 102 (i.e., the closest to the processing chamber 101) along the arrangement direction P among the electrodes 115, 116 and 117 as the components included in the grid unit 109.

In this embodiment, the first electrode 115 is connected to a first power source (not shown) and a positive voltage is applied thereto. The second electrode 116 is connected to a second power source (not shown) and a negative voltage is applied thereto. Therefore, when the plasma is generated in the plasma generation chamber 102 and the positive voltage is applied to the first electrode 115 and the negative voltage is applied to the second electrode 116, the ions are accelerated by a potential difference between the first electrode 115 and the second electrode 116. Meanwhile, the third electrode 117 is also called an earth electrode, which is grounded. An ion beam diameter of the ion beam can be controlled within a predetermined numerical range using an electrostatic lens effect by controlling a potential difference between the second electrode 116 and the third electrode 117.

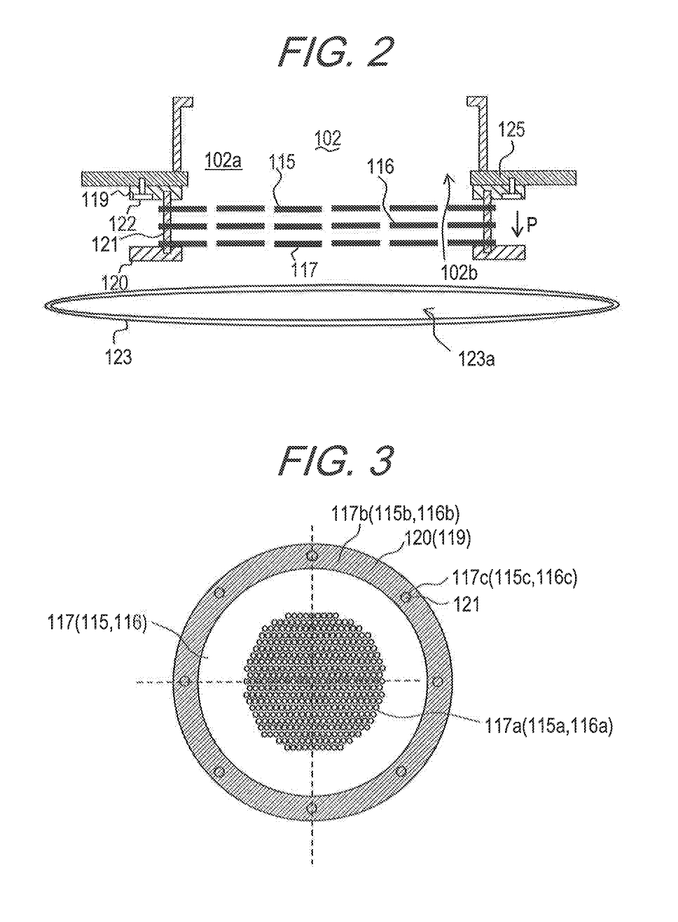

FIG. 2 is a schematic enlarged view of the vicinity of the grid unit 109. The first electrode 115, the second electrode 116 and the third electrode 117 are connected by fixing members 121 each having one end and another end. Specifically, each of the fixing members 121 penetrates through through-holes formed in a peripheral portion outside the region of each of the first electrode 115, the second electrode 116 and the third electrode 117 where the plurality of ion passage holes are formed. Moreover, the one end of the fixing member 121 is fixed to a first ring 119 which is a first ring member. The other end of the fixing member 121 is fixed to a second ring 120 which is a second ring member.

FIG. 3 is a diagram showing the third electrode 117 (the first electrode 115) and the second ring 120 (the first ring 119) as seen from the substrate side (the internal space 102a side). In a peripheral portion 117b of the third electrode 117 on the outside of the region where ion passage holes 117a are formed, a plurality of through-holes 117c are provided, through which the fixing members 121 penetrate. Also, in a peripheral portion 116b of the second electrode 116 on the outside of the region where ion passage holes 116a are formed, a plurality of through-holes 116c are formed, through which the fixing members 121 penetrate. Moreover, in a peripheral portion 115b of the first electrode 115 on the outside of the region where ion passage holes 115a are formed, a plurality of through-holes 115c are provided, through which the fixing members 121 penetrate.

The second ring 120 is provided overlapping with the peripheral portion 117b described above such that the large number of ion passage holes 117a provided in the third electrode 117 are exposed through the second ring 120. The respective fixing members 121 penetrating through the respective through-holes 117c are connected to the second ring 120. Likewise, the first ring 119 is provided overlapping with the peripheral portion 115b described above such that the large number of ion passage holes 115a provided in the first electrode 115 are exposed through the first ring 119. The respective fixing members 121 penetrating through the respective through-holes 115c are connected to the first ring 119. The fixing members 121 connect the first ring 119 to the second ring 120 by penetrating through the through-holes 115c, 116c and 117c in the first electrode 115, the second electrode 116 and the third electrode 117.

As described above, in this embodiment, the first electrode 115, the second electrode 116 and the third electrode 117 are penetrated by the fixing members 121, and the both ends of the fixing members 121 are connected to the first ring 119 and the second ring and 120, respectively. Thus, positional misalignment among the first electrode 115, the second electrode 116 and the third electrode 117 can be suppressed. As a result, relative positional misalignment among the respective ion passage holes can be prevented or reduced.

As shown in FIG. 2, the first ring 119 described above is attached to a side wall 125 of the processing chamber 101 by fastening members 122. Therefore, the first ring 119 is provided closer to the internal space 102a (closer to the plasma generation chamber 102) along the arrangement direction P than the first electrode 115. On the other hand, the second ring 120 is provided farther from the internal space 102a than where the third electrode 117 is provided, i.e., on the side of the third electrode 117 opposite to the second electrode 116 (farther from the plasma generation chamber 102, i.e., on the processing chamber side), along the arrangement direction P described above.

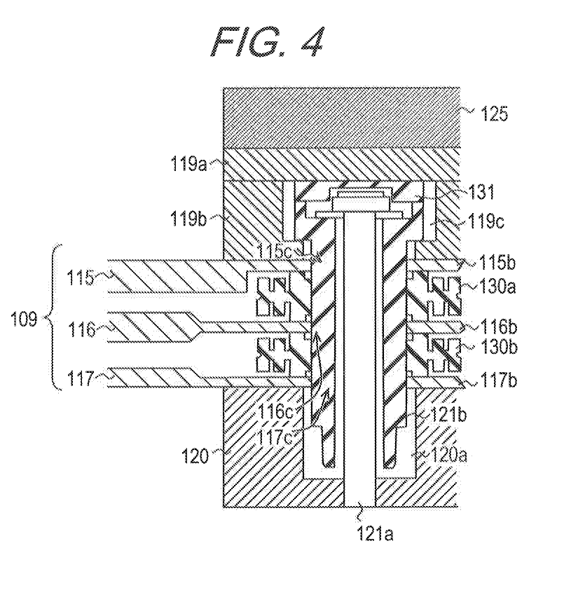

FIG. 4 is a detailed diagram showing the connection between the grid unit 109 and the first and second rings 119 and 120 according to this embodiment. The first ring 119 includes a cap ring 119a and a bottom ring 119b. As for a material of the cap ring 119a, stainless steel or aluminum, for example, can be used. As for a material of the bottom ring 119b, it is preferable that the material is determined based on a relationship between a coefficient of thermal expansion of the bottom ring 119b and that of a material of the grid unit 109. Specifically, it is preferable that the material of the bottom ring 119b has a coefficient of thermal expansion, which is equivalent to that of the material of the grid unit 109, particularly, that of the material of the first electrode 115 that comes into contact with the bottom ring 119b. To be more specific, as for the material of the bottom ring 119b, molybdenum, titanium, carbon, iron-nickel alloy, stainless steel, tungsten or the like can be used, for example.

The cap ring 119a is attached to the side wall 125 of the processing chamber 101. The bottom ring 119b is attached to the cap ring 119a. In the bottom ring 119b, a through-hole 119c, through which the fixing member 121 penetrates, is formed so as to correspond to the respective through-holes 115c, 116c and 117c formed in the first electrode 115, the second electrode 116 and the third electrode 117. As described later, after the fixing member 121 penetrates through the through-hole 119c, the one end of the fixing member 121 is fitted in the through-hole 119c. In other words, the through-hole 119c is an opening in which the fixing member 121 is fitted.

The bottom ring 119b comes into contact with the first electrode 115 such that the through-hole 119c and the through-hole 115c face each other. The second electrode 116 is disposed at a distance from the first electrode 115 such that the through-hole 116c and the through-hole 115c face each other. Between the peripheral portion 115b of the first electrode 115 and the peripheral portion 116b of the second electrode 116, an insulator 130a is disposed as a spacer. Likewise, the third electrode 117 is disposed at a distance from the second electrode 116 such that the through-hole 117c and the through-hole 116c face each other. Between the peripheral portion 116b of the second electrode 116 and the peripheral portion 117b of the third electrode 117, an insulator 130b is disposed as a spacer. As for materials of these insulators 130a and 130b, it is preferable that the materials are determined based on a relationship between coefficients of thermal expansion of the insulators 130a and 130b, and that of the material of the grid unit 109. Specifically, it is preferable that the material of the insulator 130a has a coefficient of thermal expansion, which is equivalent to that of the material of the grid unit 109, particularly, those of the first electrode 115 and the second electrode 116 that come into contact with the insulator 130a. Likewise, it is preferable that the material of the insulator 130b has a coefficient of thermal expansion, which is equivalent to that of the material of the grid unit 109, particularly, those of the second electrode 116 and the third electrode 117 that come into contact with the insulator 130b. To be more specific, as for the materials of the insulators 130a and 130b, ceramics, aluminum oxide or the like can be used, for example.

The second ring 120 has a concave part 120a formed therein as an opening in which the fixing member 121 is fitted, so as to correspond to the respective through-holes 115c, 116c and 117c formed in the first electrode 115, the second electrode 116 and the third electrode 117. The second ring 120 comes into contact with the third electrode 117 such that the concave part 120a and the through-hole 117c face each other. As for a material of the second ring 120, it is preferable that the material is determined based on a relationship between a coefficient of thermal expansion of the second ring 120 and that of the material of the grid unit 109. Specifically, it is preferable that the material of the second ring 120 has a coefficient of thermal expansion, which is equivalent to that of the material of the grid unit 109, particularly, that of the material of the third electrode 117 that comes into contact with the second ring 120. To be more specific, as for the material of the second ring 120, titanium, stainless steel, tungsten or the like can be used, for example.

Note that the present invention is not limited to the configuration described above as long as the fixing member 121 penetrating through the first electrode 115, the second electrode 116 and the third electrode 117 is fixed by the first ring 119 and the second ring 120. In this case, the bottom ring 119b, i.e., the first ring 119 does not need to come into contact with the first electrode 115. Furthermore, the second ring 120 and the third electrode 117 do not need to come into contact with each other.

With the above configuration, the through-holes 119c, 115c, 116c and 117c and the concave part 120a are arranged in alignment with each other. In this embodiment, the fixing member 121 includes a metal fixing bolt 121a and an insulator 121b provided so as to cover the metal fixing bolt 121a. The fixing member 121 having the insulator 121b on its surface as described above is screwed into the concave part 120a through the through-holes 119c, 115c, 116c and 117c. In this event, the insulator 121b has regions that come into contact with respective walls of the through-holes 119c, 115c, 116c and 117c and the concave part 120a. In other words, the fixing member 121 has regions that come into contact with the first ring 119, the first electrode 115, the second electrode 116, the third electrode 117 and the second ring 120, respectively. Thus, the metal fixing bolt 121a is insulated from the first ring 119, the first electrode 115, the second electrode 116, the third electrode 117 and the second ring 120. Also, the metal fixing bolt 121a is insulated from the cap ring 119a by an insulating cap 131. As for materials of the insulator 121b and the insulating cap 131, ceramics and aluminum oxide can be used, for example, as long as the materials have insulating properties. Note that, in this embodiment, the fixing member 121 may have an insulating layer at least on its surface, and may be an insulator itself as long as the insulator has a certain degree of rigidity.

In this embodiment, the ion beam generator 100 further includes a lamp heater 123 in the processing chamber 101 as a heating unit configured to heat the third electrode 117 from outside of the plasma generation chamber 102. As shown in FIGS. 1 and 2, the lamp heater 123 has a shape of a ring including an opening 123a. The ring-shaped lamp heater 123 is provided on the side of the second ring 120 opposite to the third electrode 117 (outside of the plasma generation chamber 102 along the arrangement direction P). The ring-shaped lamp heater 123 is disposed such that the grid unit 109 is included in the opening 123a. Thus, the ion beam extracted by the grid unit 109 exits from the opening 123a of the ring-shaped lamp heater 123. The lamp heater 123 heats the third electrode 117 from the processing chamber 101 side, i.e., from the outside of the plasma generation chamber 102.

The second ring 120 having the fixing members 121 connected thereto is provided between the lamp heater 123 and the third electrode 117. Thus, the lamp heater 123 also heats the fixing member 121. Therefore, it can also be said that the lamp heater 123 is provided to heat not only the third electrode 117 but also the fixing member 121.

In this embodiment, the lamp heater 123 for heating the third electrode 117 in the grid unit 109 is provided on the side of the grid unit 109 opposite to the internal space 102a in which plasma discharge occurs. Thus, the third electrode 117 can be set to a predetermined temperature by heating the third electrode 117 with the lamp heater 123 during formation of plasma in the internal space 102a. Therefore, even if the temperature of the first electrode 115 is increased by heat from the plasma, a temperature difference between the first electrode 115 and the third electrode 117 can be reduced. Thus, in this embodiment, a difference in thermal expansion between the first electrode 115 and the third electrode 117 can be reduced. As a result, deflection of the first electrode 115 and the third electrode 117 can be suppressed. Thus, positional misalignment between the ion passage holes (grid holes) in the third electrode 117 that is the grid on the substrate 111 side and the ion passage holes (grid holes) in the first electrode 115 that is the grid on the plasma side can be reduced. Moreover, gap differences among the first electrode 115, the second electrode 116 and the third electrode 117 as the grids can be reduced. Thus, according to this embodiment, the positional misalignment of the grid holes between the substrate side and the plasma side as well as the gap differences among the grids can be reduced. Furthermore, load attributable to a difference in thermal expansion on the fixing member 121 and the first to third electrodes 115 to 117 can be reduced.

Since a large part of the first electrode 115 is exposed to plasma, the first electrode 115 is heated by the heat of plasma in the plasma generation chamber 102. However, the first ring 119 is less exposed to the plasma and thus is not heated as much as the first electrode 115. The first electrode 115 serves as a thermal screen for the second electrode 116 and the third electrode 117. Therefore, the second electrode 116 and the third electrode 117 are less affected by the heat of plasma in the internal space 102a. Thus, the second electrode 116 and the third electrode 117 are not heated as much as the first electrode 115. Therefore, in a conventional case where there is no heating unit provided for directly heating the third electrode 117 from outside of the plasma generation chamber 102, such as the lamp heater 123, there may arise a large difference in temperature between the first electrode 115 and the third electrode 117. This temperature difference causes the difference in thermal expansion described above. In this embodiment, on the other hand, the third electrode 117 that is not heated much by the heat of plasma generated in the internal space 102a is heated by the lamp heater 123 in addition to the above described heat of plasma. Therefore, even if the heat of plasma does not act much on the third electrode 117, the third electrode 117 can be heated to a predetermined temperature. Thus, a temperature difference between the first electrode 115 and the third electrode 117 can be reduced during generation of plasma.

Furthermore, in this embodiment, since the second ring 120 is exposed to the lamp heater 123, the second ring 120 and the fixing member 121 connected to the second ring 120 are also largely affected by the heat from the lamp heater 123. In other words, the second ring 120 and the fixing member 121 are efficiently heated by the lamp heater 123. The fixing member 121 comes into contact with at least a part of each of the first ring 119, the first electrode 115, the second electrode 116, the third electrode 117 and the second ring 120. Thus, the heat of the second ring 120 and the fixing member 121 heated by the lamp heater 123 can be transmitted not only to the third electrode 117 but also to the second electrode 116 and the first electrode 115. Therefore, the lamp heater 123 can improve the uniformity of heating of the first electrode 115, the second electrode 116 and the third electrode 117.

In this embodiment, from the viewpoint of efficient heating of the third electrode 117, it is preferable that the third electrode 117 and the second ring 120 are in contact with each other. If the third electrode 117 and the second ring 120 are in contact with each other as described above, the third electrode 117 can also be heated by heat conduction from the second ring 120 heated by the lamp heater 123 in addition to the heat radiated from the lamp heater 123. Thus, the third electrode 117 can be efficiently heated.

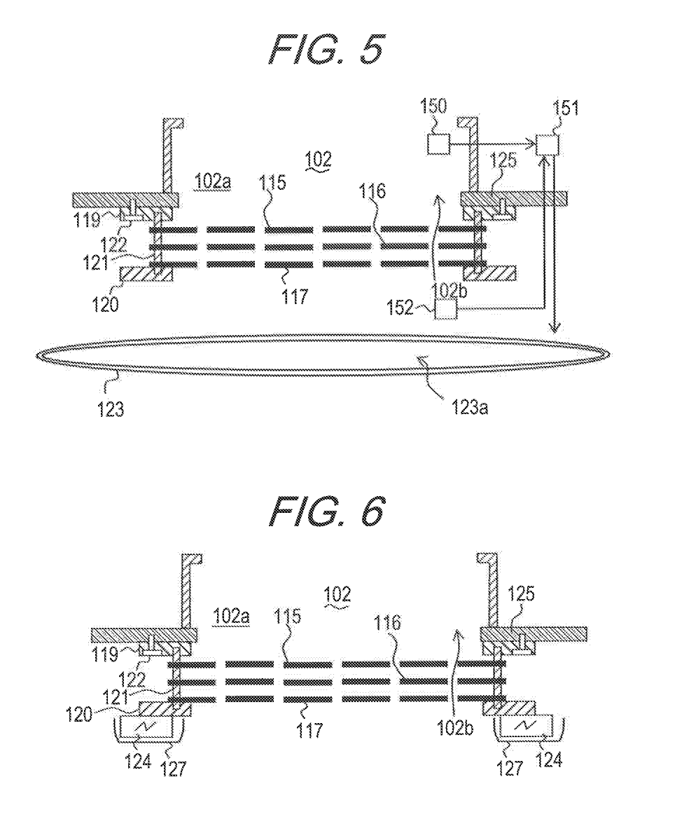

Note that, in this embodiment, the temperature of the first electrode 115 may be detected, and heating by the lamp heater 123 may be controlled based on the detection result. In this case, as shown in FIG. 5, for example, a temperature detection sensor 150 for detecting the temperature of the first electrode 115 is provided in the plasma generation chamber 102 to detect the temperature of the first electrode 115. The temperature detection sensor 150 transmits the detection result to a controller 151 configured to control drive of the lamp heater 123. Also, a temperature detection sensor 152 for detecting the temperature of the third electrode 117 is provided in the processing chamber 101 to detect the temperature of the third electrode 117. The temperature detection sensor 152 transmits the detection result to the controller 151.

The controller 151 controls heating by the lamp heater 123 based on information about the temperature of the first electrode 115 received from the temperature detection sensor 150 and information about the temperature of the third electrode 117 received from the temperature detection sensor 152. Specifically, the controller 151 monitors the current temperature of the third electrode 117 based on the detection result from the temperature detection sensor 152. The controller 151 controls heating by the lamp heater 123 by setting the current temperature of the first electrode 115, which is obtained from the detection result from the temperature detection sensor 150, as a target temperature while monitoring the current temperature of the third electrode 117. The controller 151 controls heating by the lamp heater 123 such that the temperature of the third electrode 117 obtained by the monitoring approaches the target temperature or approximately the same as the target temperature. Thus, a temperature difference between the first electrode 115 and the third electrode 117 can be reduced.

### Second Embodiment

Although, in the first embodiment, the lamp heater 123 disposed at a distance from the second ring 120 is used as the heating unit configured to heat the third electrode 117 from outside of the plasma generation chamber 102, the heating unit is not limited thereto. The heating unit may be one capable of heating the third electrode 117, and is preferably one capable of heating the third electrode 117 and the fixing member 121. As the above heating unit, any type of unit may be used, such as resistance heating type, induction heating type, dielectric heating type and radiation heating type, for example, as long as predetermined members can be heated. In this embodiment, description is given of a configuration using a heating wire that is an example of the resistance heating type, as the above heating unit.

FIG. 6 is a schematic diagram for explaining the above heating unit according to this embodiment. In FIG. 6, a heating wire 124 is provided along a circumferential direction of the second ring 120 so as to come into contact with the second ring 120 on the side of the second ring 120 opposite to the third electrode 117. The third electrode 117 and the second ring 120 are in contact with each other. An unillustrated power source is connected to the heating wire 124. The second ring 120 can be heated by applying a predetermined voltage from the heating wire 124. In this embodiment, since the second ring 120 and the third electrode 117 are in contact with each other, heat generated in the second ring 120 by the heating wire 124 is transferred to the third electrode 117, and the third electrode 117 can be heated by the transferred heat. Moreover, the second ring 120 and the fixing member 121 are connected to each other. Thus, the heat generated in the second ring 120 by the heating wire 124 is transferred through the fixing member 121, and both of the second electrode 116 and the first electrode 115 can also be heated by the transferred heat.

Moreover, in this embodiment, since the heating wire 124 is in contact with the second ring 120, the heat from the heating wire 124 can be efficiently transferred to the third electrode 117, the second electrode 116 and the first electrode 115. Thus, a temperature distribution among the first to third electrodes 115 to 117 can be reduced. Furthermore, a temperature difference among the respective electrodes can also be reduced.

Moreover, on the processing chamber 101 side of the heating wire 124, an adhesion prevention cover 127 is provided so as to cover the heating wire 124 from the processing chamber 101 side. When the adhesion prevention cover 127 is not provided, a scattered substance from etching also eventually adheres to the heating wire 124. Therefore, the adhesion prevention cover 127 provided so as to cover the heating wire 124 as shown in FIG. 6 facilitates maintenance. Note that the adhesion prevention cover 127 does not necessarily to be provided.

### Third Embodiment

The fixing member 121 may be configured so as to be slidable with respect to at least one of the first ring 119 and the second ring 120. With such a configuration, the fixing member 121 can be freely elongated and contracted regardless of coefficients of thermal expansion of the first ring 119 and the second ring 120. Thus, the load applied to the fixing member 121 and the first to third electrodes 115 to 117 can be further reduced.

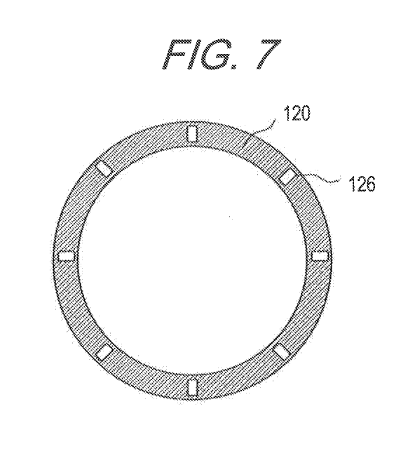

FIG. 7 is a diagram showing the second ring 120 when the fixing member 121 is configured to be slidable with respect to the second ring 120. FIG. 7 shows a state of the second ring 120 as seen from the first ring 119 side.

In FIG. 7, opening portions 126 are formed so as to make the fixing member 121 slidable in a radial direction of the second ring 120, instead of the concave part 120a in the first embodiment, on the circumference of the second ring 120. The opening portions 126 are for fixing the other ends of the fixing members 121, and are provided so as to face the through-holes 117c in the third electrode 117. The fixing members 121 are connected to the second ring 120 by inserting the other ends of the fixing members 121 penetrating through the through-holes 117c into the opening portions 126.

In this embodiment, each of the opening portions 126 has a rectangular shape with round corners, and a width thereof in the radial direction of the second ring 120 is longer than that in the circumferential direction of the second ring 120. The other ends of the fixing members 121 are inserted into the opening portions 126 and connected to the second ring 120 so as to be slidable along the radial direction of the second ring 120. Note that it is preferable to set the diameter of the fixing members 121 and the width of the opening portions 126 in the circumferential direction such that the inserted fixing members 121 slide in the radial direction against wall surfaces of the opening portions 126 along the radial direction while coming into contact with the wall surfaces.

With such a shape, the fixing members 121 slide along the radial direction of the second ring 120 with respect to the second ring 120 even when the second ring 120 is thermally expanded by heating with the lamp heater 123, the heating wire 124 or the like. Thus, the load on the fixing members 121 and the second ring 120 can be further reduced.

Moreover, even when the second ring 120 differs from any of the electrodes (the first electrode 115, the second electrode 116 and the third electrode 117) in the grid unit 109 in coefficient of thermal expansion, the fixing members 121 can slide within the opening portions 126 so as to compensate for a difference in thermal expansion. Thus, the load on the fixing members 121 and the respective electrodes in the grid unit 109 can be further reduced.

The opening portions 126 described above can also be provided in the first ring 119. In this case, the opening portions 126 are provided instead of the through-holes 119c in the first embodiment in the first ring 119. The opening portions 126 provided in the first ring 119 are for fixing the one ends of the fixing members 121, and are provided so as to face the through-holes 115c in the first electrode 115. The fixing members 121 are connected to the first ring 119 by inserting the one ends of the fixing members 121 penetrating through the through-holes 115c into the opening portions 126 in the first ring 119. The one ends of the fixing members 121 are inserted into the opening portions 126 and connected to the first ring 119 so as to be slidable along the radial direction of the first ring 119.

Note that the opening portions 126 can also be provided in both of the first ring 119 and the second ring 120 or in any one of the first ring 119 and the second ring 120.

What is claimed is:

1. An ion beam etching apparatus comprising:
a plasma generation chamber including an internal space;
a processing chamber connected to the plasma generation chamber;
a plasma generating unit configured to generate plasma in the internal space;
an extracting unit configured to extract ions from the plasma, from the internal space to the processing chamber, the extracting unit including a first electrode, a second electrode and a third electrode, each of which has a plurality of ion passage holes for passing the ions, the first electrode being provided closest to the plasma generation chamber, the second electrode being provided closer to the processing chamber than the first electrode, the third electrode being provided closest to the processing chamber;
a first ring member provided closer to the plasma generation chamber than the first electrode, the first ring member overlapping with a peripheral portion of the first electrode outside a region where the plurality of ion passage holes in the first electrode are formed, such that the plurality of ion passage holes formed in the first electrode are exposed through the first ring member;
a second ring member provided closer to the processing chamber than the third electrode, the second ring member overlapping with a peripheral portion of the third electrode outside a region where the plurality of ion passage holes in the third electrode are formed, such that the plurality of ion passage holes formed in the third electrode are exposed through the second ring member;
a fixing member having one end and another end, the fixing member penetrating the first electrode, the second electrode and the third electrode, and having the one end connected to the first ring member and the other end connected to the second ring member;
a heating unit configured to heat the third electrode from outside of the plasma generation chamber; and
a substrate holder provided in the processing chamber and capable of holding a substrate, the substrate holder being provided to receive the ions extracted by the extracting unit.

2. The ion beam etching apparatus according to claim 1,
wherein the first, second and third electrodes are each provided with a plurality of through-holes, through each of which the fixing member penetrates, in a region on the outside from the region where the plurality of ion passage holes are formed, and
wherein the fixing member is fixed to the first ring member and the second ring member by penetrating through the through-holes in the first, second and third electrodes and thereby connecting the first ring member to the second ring member.

3. The ion beam etching apparatus according to claim 1,
wherein the heating unit heats the second ring member.

4. The ion beam etching apparatus according to claim 1, further comprising:
an adhesion prevention cover provided so as to cover the heating unit.

5. The ion beam etching apparatus according to claim 2,
wherein an opening into which the fixing member is inserted is formed in at least one of the first ring member and the second ring member,
wherein the opening has a shape in which a width in a radial direction of the ring member is longer than a width in a circumferential direction of the ring member, and
wherein the shape allows the fixing member to slide in the opening.

6. An ion beam generator comprising:
a plasma generation chamber including an internal space;
a plasma generating unit configured to generate plasma in the internal space;
an extracting unit configured to extract ions from the plasma, from the internal space to an outside of the plasma generation chamber, the extracting unit including a first electrode, a second electrode and a third electrode, each of which has a plurality of ion passage holes for passing the ions and which are arranged along a predetermined direction such that surfaces where the ion passage holes are formed face each other, the first electrode being provided closest to the plasma generation chamber, the third electrode being provided farthest from the plasma generation chamber along the predetermined direction and the second electrode being provided between the first electrode and the third electrode;
a first ring member provided closer to the plasma generation chamber than the first electrode, the first ring member overlapping with a peripheral portion of the first electrode outside a region where the plurality of ion passage holes in the first electrode are formed, such that the plurality of ion passage holes formed in the first electrode are exposed through the first ring member;
a second ring member provided farther from the plasma generation chamber along the predetermined direction than the third electrode, the second ring member overlapping with a peripheral portion of the third electrode outside the region where the plurality of ion passage holes in the third electrode are formed, such that the plurality of ion passage holes formed in the third electrode are exposed through the second ring member;
a fixing member having one end and another end, the fixing member penetrating the first electrode, the second electrode and the third electrode, and having the one end connected to the first ring member and the other end to the second ring member; and
a heating unit configured to heat the third electrode from outside of the plasma generation chamber.
